(19) United States
(12) Patent Application Publication
(10) Pub. No.: US 2026/0231438 A1
(43) Pub. Date: Aug. 6, 2026

(54) SEMICONDUCTOR DEVICE AND MANUFACTURING METHOD THEREOF

(71) Applicant: Winbond Electronics Corp., Taichung City (TW)

(72) Inventors: Jin-Neng Wu, Kaohsiung City (TW); Shuo-Che Chang, Taichung (TW); Cheng-Wei Chen, Taichung City (TW); Yu-Cheng Chen, Kaohsiung City (TW)

(73) Assignee: Winbond Electronics Corp., Taichung City (TW)

(21) Appl. No.: 19/235,598

(22) Filed: Jun. 12, 2025

(30) Foreign Application Priority Data
Feb. 3, 2025 (TW) 114103826

(51) Int. Cl. H10B 80/00; H10W 90/00; H10W 72/00; H10W 80/00; H10W 90/20

(52) U.S. Cl. CPC H10B 80/00; H10W 90/00; H10W 72/823; H10W 80/312; H10W 80/327; H10W 90/288; H10W 90/297; H10W 90/722; H10W 90/792

(57) ABSTRACT

A semiconductor device is provided, the semiconductor device includes a circuit substrate, an interposer, a memory stack layer and a system on chip. The interposer is bonded to the substrate. The memory stack layer is bonded to the interposer and electrically connected to the substrate through the interposer. The memory stack layer includes a plurality of memory dies stacked together. The system on chip is bonded to the memory stack layer. The memory stack layer is located between the system on chip and the interposer.

### CROSS-REFERENCE TO RELATED APPLICATION

This application claims the priority benefit of Taiwan application serial no. 114103826, filed on February 3, 2025. The entirety of the above-mentioned patent application is hereby incorporated by reference herein and made a part of this specification.

### BACKGROUND

### Technical Field

The present invention relates to a semiconductor device and a method of manufacturing the same.

### Related Art

As the economic benefits of Moore's Law diminish, optimizing semiconductor device performance can no longer rely solely on process improvements. The industry has shifted from simply improving processes to increase the number of transistors per unit area on a single silicon chip, to utilizing complex system level chip designs to enhance the overall performance of semiconductor devices. Among these, the chiplet technology has garnered significant attention, as it can achieve higher transistor density and performance at relatively lower costs.

Three-dimensional (3D) packaging is a new semiconductor device design concept that divides the various components originally contained in a single chip into separate small units, each of which is redesigned and remanufactured to enhance functionality, and ultimately integrates multiple small units into a semiconductor device through advanced packaging technology. To increase the number of chiplets included in the semiconductor device, many manufacturers are dedicated to developing technologies for stacking multiple chiplets together.

### SUMMARY

The present invention provides a semiconductor device, including a substrate, an interposer layer, a memory stack layer, and a system on chip. The interposer layer is bonded to the substrate. The memory stack layer is bonded to the interposer layer and electrically connected to the substrate through the interposer layer. The memory stack layer includes multiple memory dies stacked together. The system on chip is bonded to the memory stack layer. The memory stack layer is located between the system on chip and the interposer layer.

The present invention provides a method of manufacturing a semiconductor device, including the following steps. A semiconductor substrate is provided. A first interconnect structure and a first bonding layer are formed on the semiconductor substrate. A memory stack layer is formed on the first interconnect structure, wherein the memory stack layer is bonded to the first bonding layer, and wherein the memory stack layer includes multiple memory dies stacked together. A system on chip is bonded to the memory stack layer, wherein the memory stack layer is located between the system on chip and the semiconductor substrate. A second interconnect structure and multiple connection terminals are formed on a side of the semiconductor substrate opposite to the first interconnect structure. The second interconnect structure are electrically connected to a substrate through the multiple connection terminals.

### BRIEF DESCRIPTION OF THE DRAWINGS

FIG. 1A to FIG. 1M are cross-sectional schematic views illustrating a method of manufacturing a semiconductor device according to an embodiment of the present invention.

FIG. 2 and FIG. 3 are cross-sectional schematic views of a semiconductor device according to different embodiments of the present invention.

FIG. 4A is a cross-sectional schematic view of a passive device according to an embodiment of the present invention.

FIG. 4B is a cross-sectional schematic view along a line a-a’ of FIG. 4A.

### DESCRIPTION OF THE EMBODIMENTS

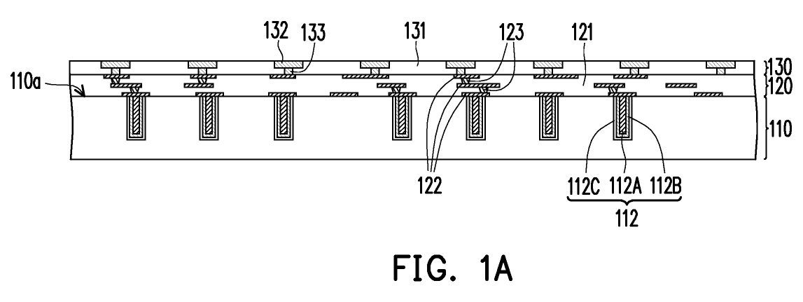

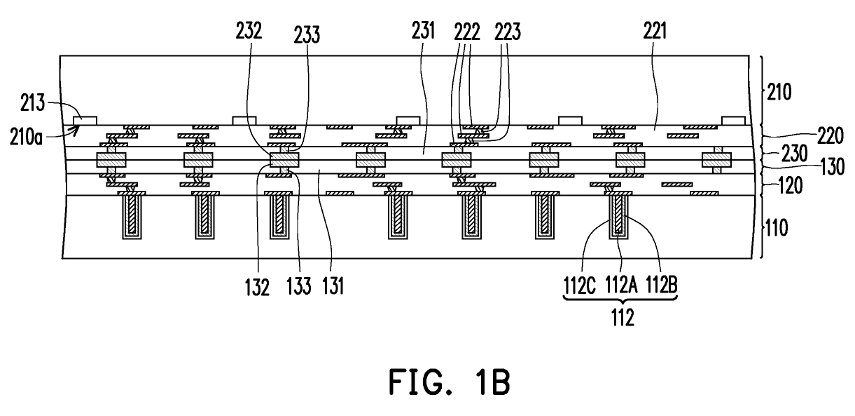

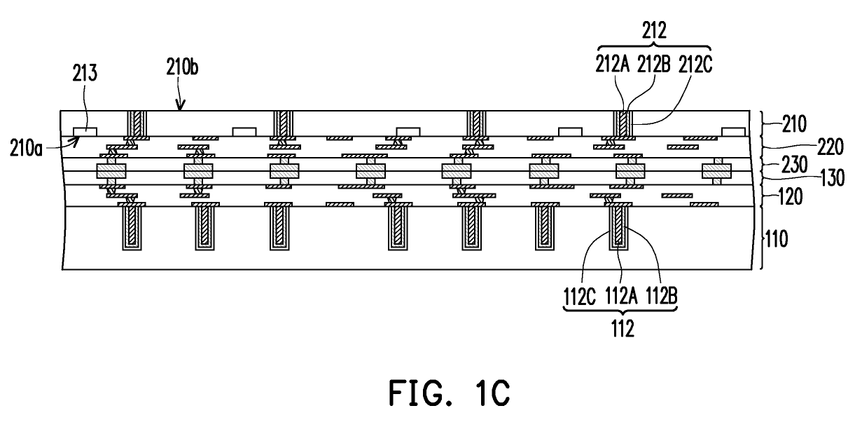

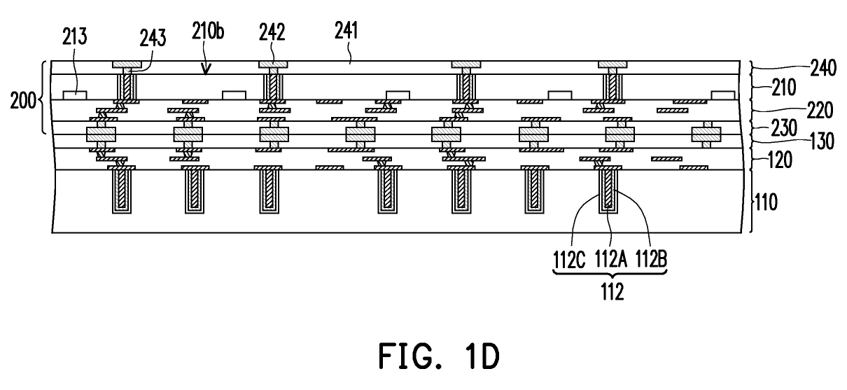

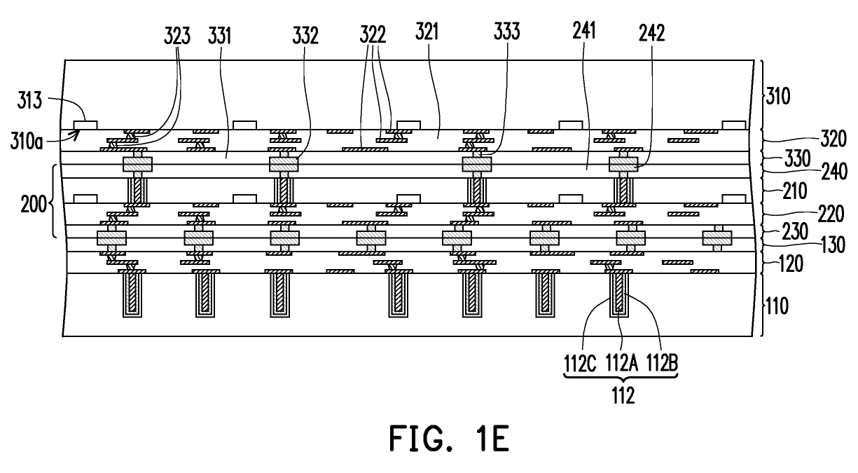

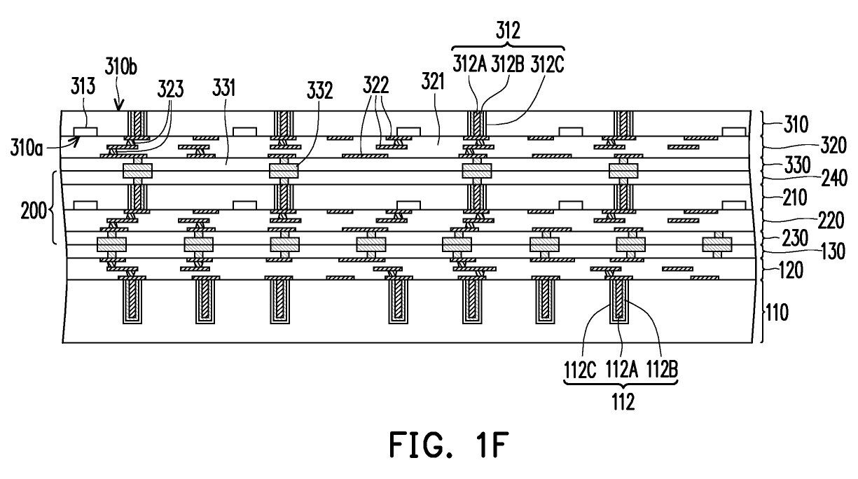

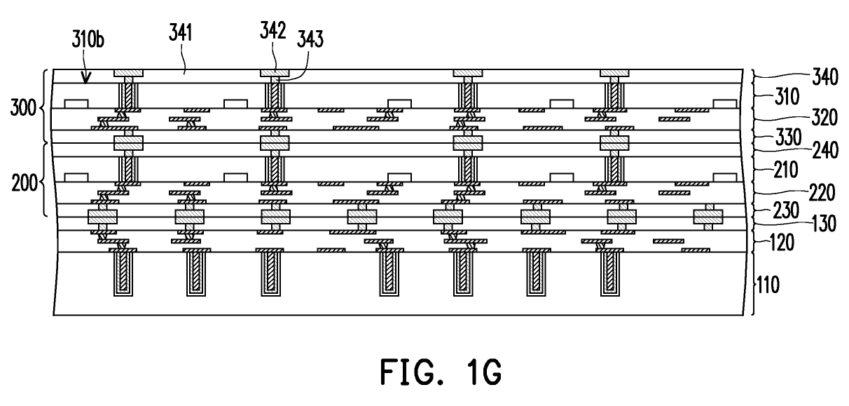

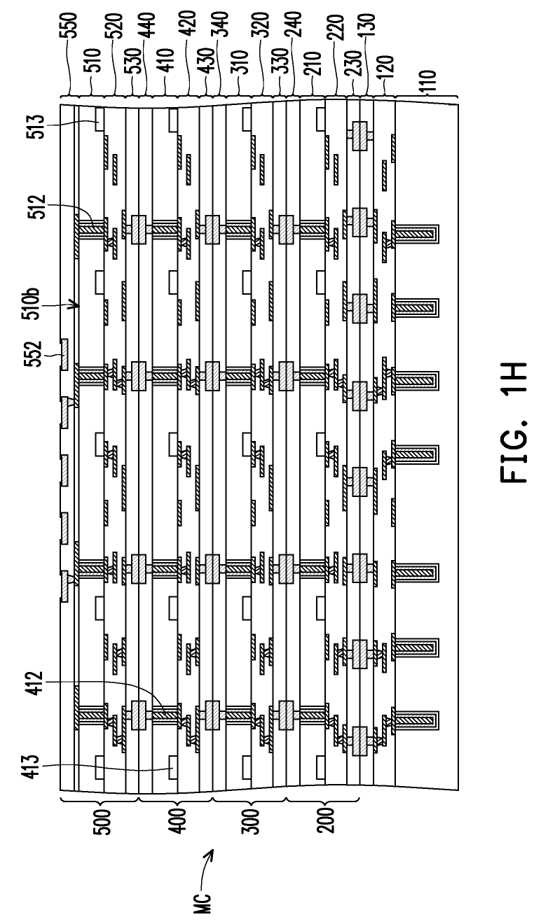

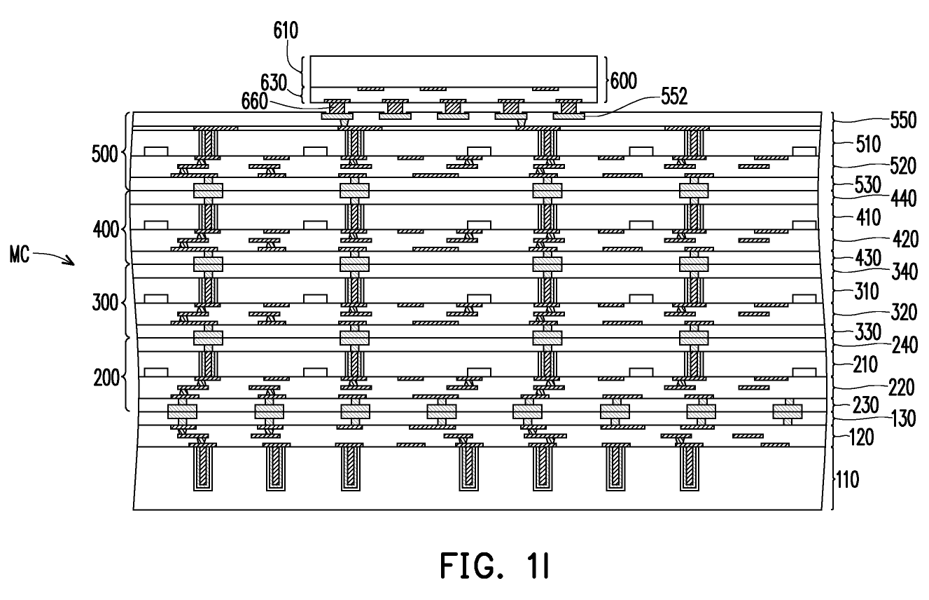

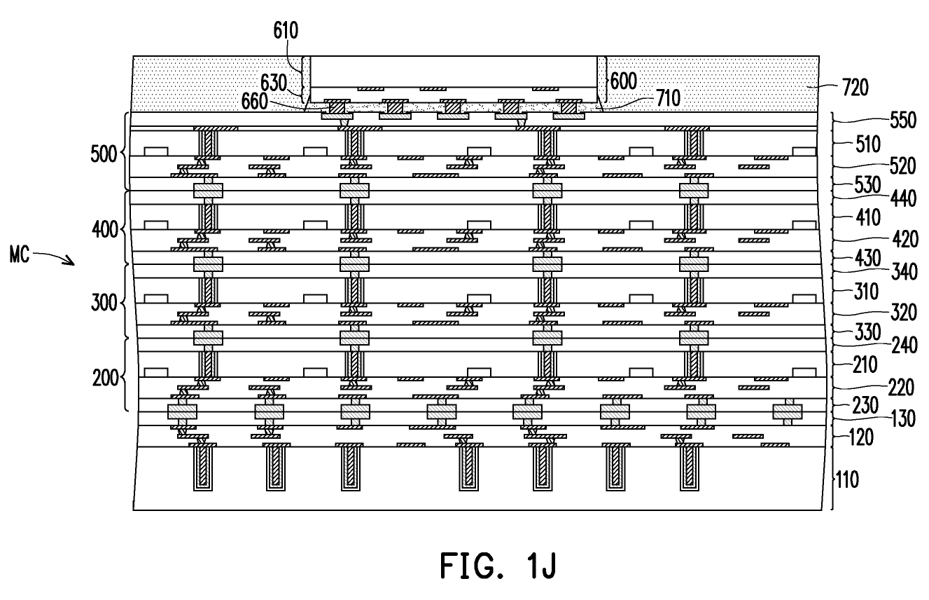

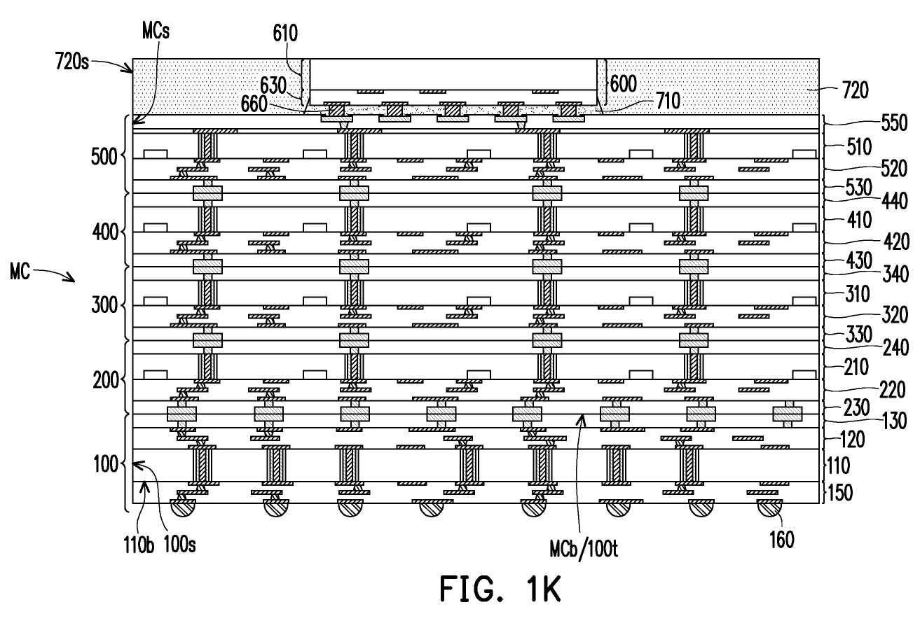

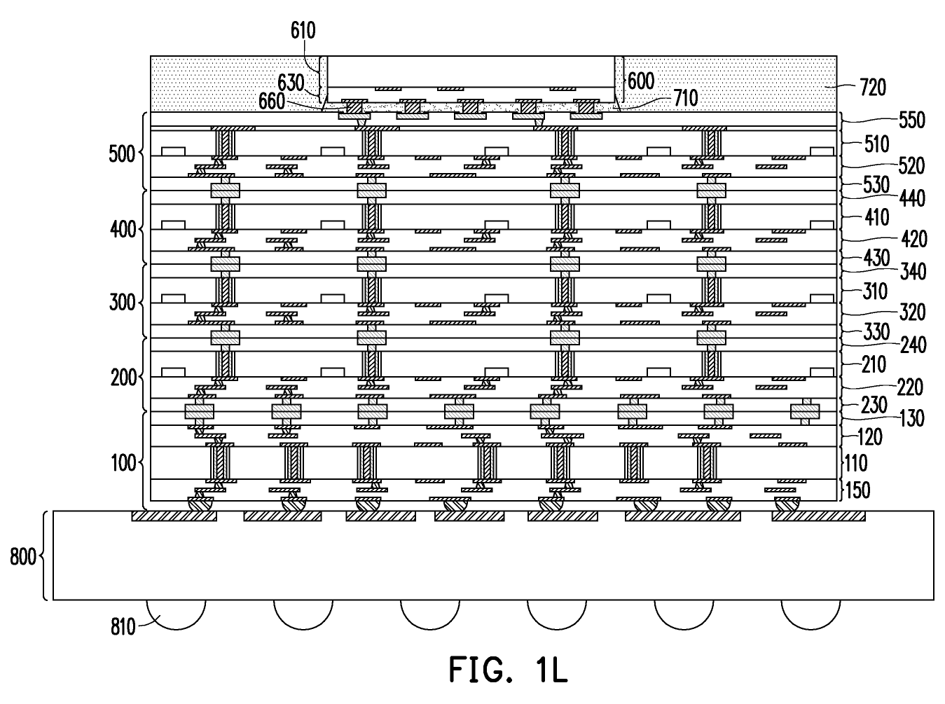

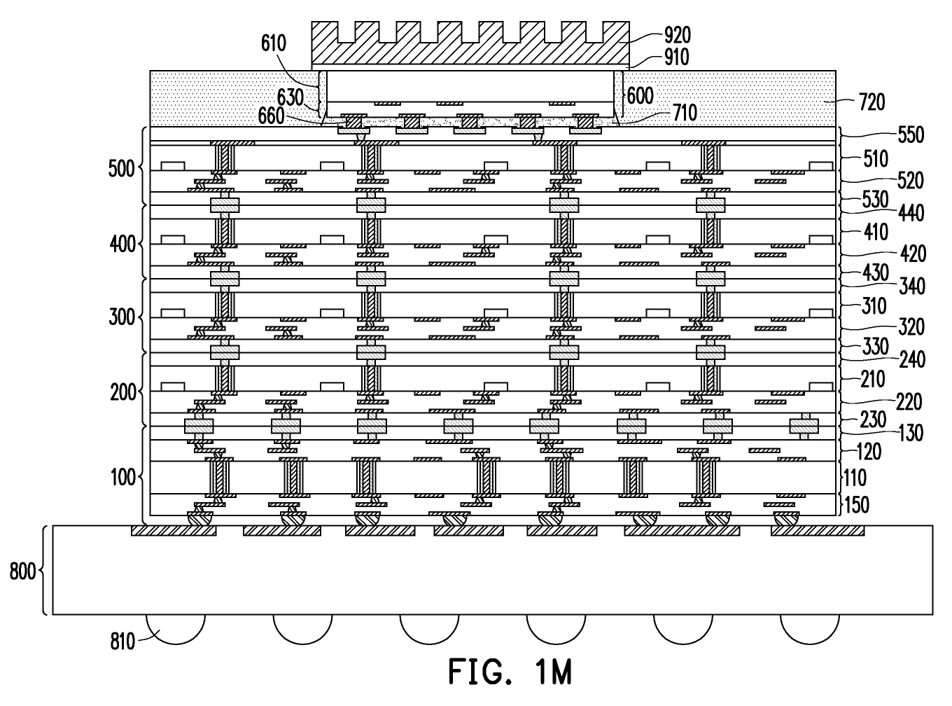

FIG. 1A to FIG. 1M are cross-sectional schematic views illustrating a method of manufacturing a semiconductor device 1 according to an embodiment of the present invention. Referring to FIG. 1A, a semiconductor substrate 110 is provided. The semiconductor substrate 110 may be an elemental semiconductor substrate (such as a silicon substrate, a germanium substrate, or the like), a compound semiconductor substrate (such as a silicon carbide substrate, a gallium arsenide substrate, or the like), or other suitable semiconductor substrate.

Multiple conductive through vias (such as through silicon vias, TSVs) 112 are disposed in the semiconductor substrate 110, extending inward from a first side 110a of the semiconductor substrate 110 into the semiconductor substrate 110. The conductive through vias 112 include a conductive filler 112A and a buffer layer 112C. A liner layer 112B may optionally be included between the conductive filler 112A and the buffer layer 112C. The buffer layer 112C includes titanium, titanium nitride, tantalum, tantalum nitride, other suitable materials, or combinations of the above materials. The liner layer 112B includes a silicide layer, or other suitable materials. The conductive filler 112A includes copper, tungsten, alloys of the above metals, or other suitable materials.

A first interconnect structure 120 is formed on the semiconductor substrate 110. The conductive through vias 112 are electrically connected to the first interconnect structure 120. The first interconnect structure 120 includes a dielectric structure 121, conductive layers 122, and conductive vias 123. The conductive layers 122 and conductive vias 123 are distributed within the dielectric structure 121. The dielectric structure 121 includes one or more insulating layers, the material of which may include silicon oxide, silicon nitride, silicon oxynitride, silicon carbide, or other suitable materials or combinations of the above materials.

A first bonding layer 130 is formed on the first interconnect structure 120. The first bonding layer 130 includes a dielectric structure 131, metal pads 132, and metal through vias 133. The metal pads 132 and metal through vias 133 are distributed within the dielectric structure 131. The material of the dielectric structure 131 includes silicon oxide or other suitable materials.

Referring to FIG. 1B to FIG. 1H, a memory stack layer MC is formed on the first interconnect structure 120. The memory stack layer MC includes multiple memory dies 200, 300, 400, 500 stacked together. Referring to FIG. 1B, an interconnect structure 220 is formed on a first semiconductor substrate 210. A first bonding layer 230 is formed on the interconnect structure 220. Then, the first bonding layer 230 is bonded to the first bonding layer 130.

The first semiconductor substrate 210 may be an elemental semiconductor substrate (such as a silicon substrate, a germanium substrate, or the like), a compound semiconductor substrate (such as a silicon carbide substrate, a gallium arsenide substrate, or the like), or other suitable semiconductor substrate. The first semiconductor substrate 210 includes an array of memory cells 213.

The interconnect structure 220 is located on a first side 210a of the first semiconductor substrate 210 and is electrically connected to the memory cells 213. The interconnect structure 220 includes a dielectric structure 221, conductive layers 222, and conductive vias 223. The conductive layers 222 and conductive vias 223 are distributed within the dielectric structure 221. The dielectric structure 221 includes one or more insulating layers, the material of which may include silicon oxide, silicon nitride, silicon oxynitride, silicon carbide, or other suitable materials or combinations of the above materials.

The first bonding layer 230 includes a dielectric structure 231, metal pads 232, and metal through vias 233. The metal pads 232 and metal through vias 233 are distributed within the dielectric structure 231. The material of the dielectric structure 231 includes silicon oxide or other suitable materials. The first bonding layer 130 and the first bonding layer 230 are connected to each other through hybrid bonding. Specifically, the metal pads 232 and the metal pads 132 are connected to each other through metal-to-metal bonding, while the dielectric structure 231 and the dielectric structure 131 are connected to each other through dielectric-to-dielectric bonding.

Referring to FIG. 1C, the second side 210b of the first semiconductor substrate 210 is ground to reduce its thickness. For example, the thickness of the first semiconductor substrate 210 may be reduced by a planarization process such as chemical mechanical planarization (CMP).

Multiple conductive through vias 212 are formed in the first semiconductor substrate 210. The conductive through vias 212 include a conductive filler 212A and a buffer layer 212C. A liner layer 212B may optionally be included between the conductive filler 212A and the buffer layer 212C. The buffer layer 212C includes titanium, titanium nitride, tantalum, tantalum nitride, other suitable materials, or combinations of the above materials. The liner layer 212B includes a silicide layer, or other suitable materials. The conductive filler 212A includes copper, tungsten, alloys of the above metals, or other suitable materials.

The conductive through vias 212 are formed on the second side 210b of the first semiconductor substrate 210 after thinning the first semiconductor substrate 210, but the present invention is not limited thereto. The conductive through vias 212 may be formed on the first side 210a of the first semiconductor substrate 210 before forming the interconnect structure 220.

Referring to FIG. 1D, a second bonding layer 240 is formed on the second side 210b of the first semiconductor substrate 210. The second bonding layer 240 includes a dielectric structure 241, metal pads 242, and metal through vias 243. The metal pads 242 and metal through vias 243 are distributed within the dielectric structure 241. The material of the dielectric structure 241 includes silicon oxide. At this point, the memory die 200 bonded to the first bonding layer 130 is substantially completed.

Referring to FIG. 1E, an interconnect structure 320 is formed on a second semiconductor substrate 310. A first bonding layer 330 is formed on the interconnect structure 320. Then, the first bonding layer 330 is bonded to the second bonding layer 240.

The second semiconductor substrate 310 may be, for example, an elemental semiconductor substrate (such as a silicon substrate, a germanium substrate, or the like), a compound semiconductor substrate (such as a silicon carbide substrate, a gallium arsenide substrate, or the like), or other suitable semiconductor substrate. The second semiconductor substrate 310 includes an array of memory cells 313.

The interconnect structure 320 is located on the first side 310a of the second semiconductor substrate 310 and is electrically connected to the memory cells 313. The interconnect structure 320 includes a dielectric structure 321, conductive layers 322, and conductive vias 323. The conductive layers 322 and conductive vias 323 are distributed within the dielectric structure 321. The dielectric structure 321 includes one or more insulation layers, the material of which may include silicon oxide, silicon nitride, silicon oxynitride, silicon carbide, other suitable materials, or combinations of the above materials.

The first bonding layer 330 includes a dielectric structure 331, metal pads 332, and metal through vias 333. The metal pads 332 and metal through vias 333 are distributed within the dielectric structure 331. The material of the dielectric structure 331 includes silicon oxide. The first bonding layer 330 and the second bonding layer 240 are connected to each other through hybrid bonding. Specifically, the metal pads 332 and metal pads 242 are connected to each other through metal-to-metal bonding, while the dielectric structure 331 and dielectric structure 241 are connected to each other through dielectric-to-dielectric bonding.

Referring to FIG. 1F, the second side 310b of the second semiconductor substrate 310 is ground to reduce its thickness. For example, the thickness of the second semiconductor substrate 310 may be reduced by a planarization process such as chemical mechanical planarization (CMP).

Multiple conductive through vias 312 are formed in the second semiconductor substrate 310. The conductive through vias 312 include conductive fillers 312A and buffer layers 312C. A liner layer 312B may optionally be included between the conductive fillers 312A and the buffer layers 312C.

The conductive through vias 312 are formed on the second side 310b of the second semiconductor substrate 310 after thinning the second semiconductor substrate 310, but the present invention is not limited thereto. The conductive through vias 312 may be formed on the first side 310a of the second semiconductor substrate 310 before forming the interconnect structure 320.

Referring to FIG. 1G, a second bonding layer 340 is formed on the second side 310b of the second semiconductor substrate 310. The second bonding layer 340 includes a dielectric structure 341, metal pads 342, and metal through vias 343. The metal pads 342 and metal through vias 343 are distributed within the dielectric structure 341. The material of the dielectric structure 341 includes silicon oxide or other suitable materials. At this point, the memory die 300 bonded to the memory die 200 is substantially completed.

The steps from FIG. 1E to FIG. 1G are repeated to form the memory die 400 on the memory die 300. The memory die 400 includes a third semiconductor substrate 410, an interconnect structure 420, a first bonding layer 430, and a second bonding layer 440. The third semiconductor substrate 410 includes conductive through vias 412 and an array of memory cells 413. The first bonding layer 430 of the memory die 400 is bonded to the second bonding layer 340 of the memory die 300 through hybrid bonding.

The steps from FIG. 1E to FIG. 1F are repeated to form a fourth semiconductor substrate 510, an interconnect structure 520, and a first bonding layer 530 on the memory die 400. The fourth semiconductor substrate 510 includes conductive through vias 512 and an array of memory cells 513. The first bonding layer 530 is bonded to the second bonding layer 440 of the memory die 400 through hybrid bonding.

An interconnect structure 550 is formed on the second side 510b of the fourth semiconductor substrate 510. The interconnect structure 550 includes multiple pads 552.

The memory stack layer MC includes four memory dies, but the present invention is not limited thereto. The steps from FIG. 1E to FIG. 1F may be repeated multiple times to include more memory dies in the memory stack layer MC.

Referring to FIG. 1I, a system on chip (SOC) device 600 is bonded to the memory stack layer MC. The memory stack layer MC is located between the system on chip 600 and the semiconductor substrate 110.

The system on chip 600 includes a semiconductor substrate 610 and an interconnect layer 630 located on the semiconductor substrate 610. Connection terminals 660 are formed on the interconnect layer 630, and the system on chip 600 is bonded to the pads 552 of the interconnect structure 550 through the connection terminals 660. The connection terminals 660 may be micro bumps or other similar structures. The spacing between the connection terminals 660 is 30 micrometers to 60 micrometers.

Referring to FIG. 1J, an underfill material 710 may optionally be formed between the system on chip 600 and the memory stack layer MC. The underfill material 710 may be used to protect the connection terminals 660 and secure the system on chip 600.

An encapsulation layer 720 is formed to encapsulate the system on chip 600. The encapsulation layer 720 laterally surrounds the system on chip 600. The encapsulation layer 720 is ground to expose the top of the system on chip 600, but the present invention is not limited thereto.

Referring to FIG. 1K, a second interconnect structure 150 and multiple connection terminals 160 are formed on the side of the semiconductor substrate 110 opposite to the first interconnect structure 120 (i.e., the second side 110b). The connection terminals 160 may be solder balls. The interposer 100 includes the semiconductor substrate 110, the first interconnect structure 120, the first bonding layer 130, the second interconnect structure 150, and the connection terminals 160. The memory stack layer MC is bonded to the interposer 100 and is located between the system on chip 600 and the interposer 100.

Subsequently, a cutting process (e.g., a singulation process) is performed on the encapsulation layer 720, the memory stack layer MC, and the interposer 100. After the cutting process, the sidewall 720s of the encapsulation layer 720, the sidewall MCs of the memory stack layer MC, and the sidewall 100s of the interposer 100 are aligned. The area of the bottom surface MCb of the memory stack layer MC (i.e., the bottom surface of the first bonding layer 230) is substantially equal to the area of the top surface 100t of the interposer 100 (i.e., the top surface of the first bonding layer 130). After the cutting process, the width of the semiconductor substrate 110 (e.g., the lateral width in FIG. 1K) is substantially equal to the width of at least one of the memory dies 200, 300, 400, 500.

Referring to FIG. 1L, the interposer 100 is electrically connected to a substrate 800. Specifically, the second interconnect structure 150 is electrically connected to the substrate 800 through the connection terminals 160. Connection terminals 810 are formed on the bottom surface of the substrate 800. The connection terminals 810 may be solder balls.

Referring to FIG. 1M, a thermal interface material layer 910 and a heat dissipation structure 920 may be formed on the system on chip 600. The thermal interface material layer 910 is located on the top surface of the system on chip 600. The heat dissipation structure 920 is located on the thermal interface material layer 910. The thermal interface material layer 910 extends from the top surface of the system on chip 600 to the top surface of the encapsulation layer 720, or the thermal interface material layer 910 may be located only on the top surface of the system on chip 600.

Since the system on chip 600 is positioned above the memory stack layer MC, the system on chip 600 is closer to the heat dissipation structure 920 compared to the memory stack layer MC. Therefore, the system on chip 600 has a better heat dissipation performance.

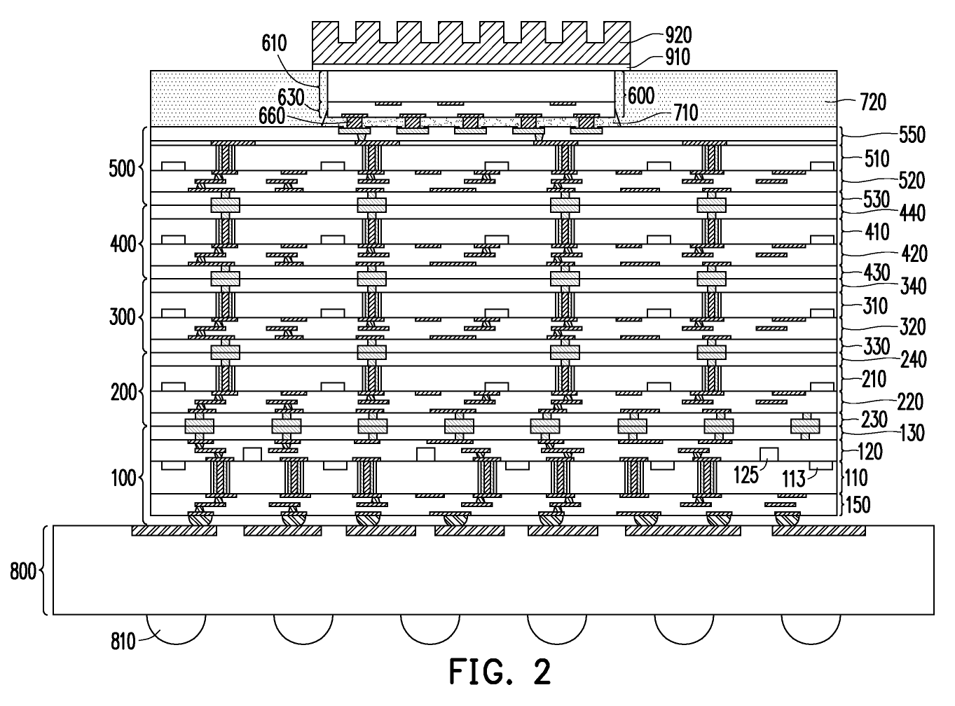

FIG. 2 is a cross-sectional schematic diagram of a semiconductor device 2 according to another embodiment of the present invention. The semiconductor device 2 in FIG. 2 resembles the semiconductor device 1 in FIG. 1M, with the difference being: in the semiconductor device 2 of FIG. 2, the interposer 100 includes a passive device 125 and an array of redundant memory 113.

The passive device 125 may be disposed in the first interconnect structure 120. The passive device 125 may be a capacitor, an inductor, a resistor, or other passive devices. The capacitor may be, for example, a cylinder capacitor, a deep trench capacitor, a metal-insulator-metal (MIM) capacitor, or other types of capacitors.

The redundant memory 113 may be used to repair the memory stack layer MC. For example, if a detection process detects that memory cells of one or more memory dies in the memory stack layer MC are damaged, a repair process can be performed to electrically connect the redundant memory 113 to the memory stack layer MC, thereby replacing the damaged memory cells.

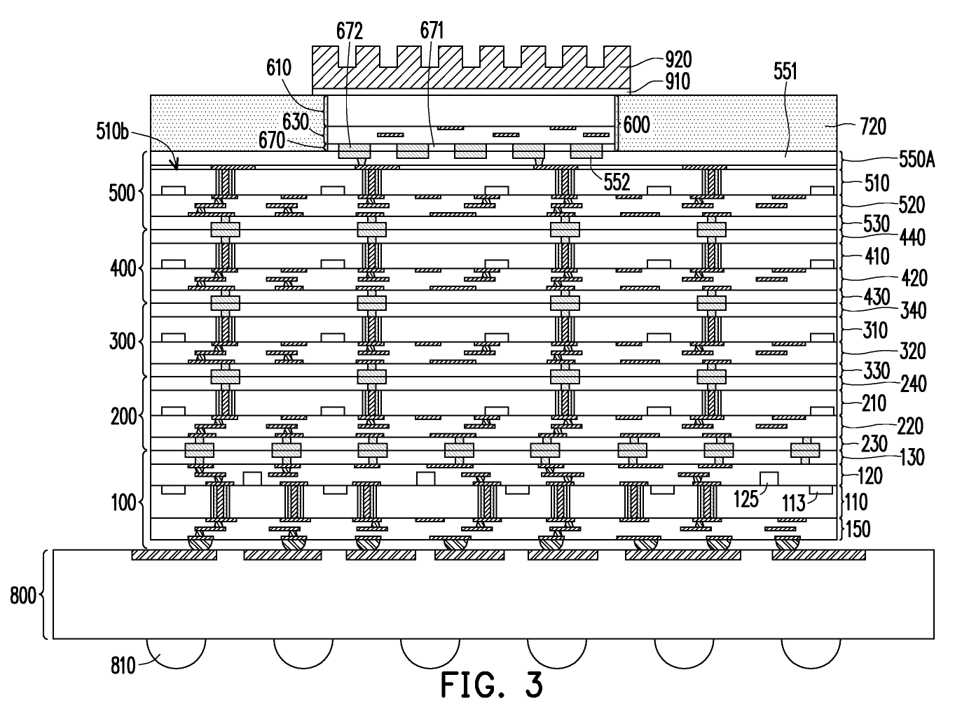

FIG. 3 is a cross-sectional schematic diagram of a semiconductor device 3 according to another embodiment of the present invention. The semiconductor device 3 in FIG. 3 resembles the semiconductor device 2 in FIG. 2, with the difference being: in the semiconductor device 3 of FIG. 3, the system on chip 600 is bonded to the memory stack layer MC through a hybrid bonding process. Specifically, the memory die 500 includes a second bonding layer 550A. The second bonding layer 550A is formed on the second side 510b of the fourth semiconductor substrate 510. The second bonding layer 550A includes a dielectric structure 551 and metal pads 552. The metal pads 552 are distributed in the dielectric structure 551. The material of the dielectric structure 551 includes silicon oxide or other suitable materials.

The system on chip 600 includes a bonding layer 670. The bonding layer 670 includes a dielectric structure 671 and metal pads 672. The metal pads 672 are distributed in the dielectric structure 671. In some embodiments, the material of the dielectric structure 671 includes silicon oxide or other suitable materials. The spacing between the metal pads 672 may be 1 micrometer to 9 micrometers.

The metal pads 672 and the metal pads 552 are connected to each other through metal-to-metal bonding, while the dielectric structure 671 and the dielectric structure 551 are connected to each other through dielectric-to-dielectric bonding.

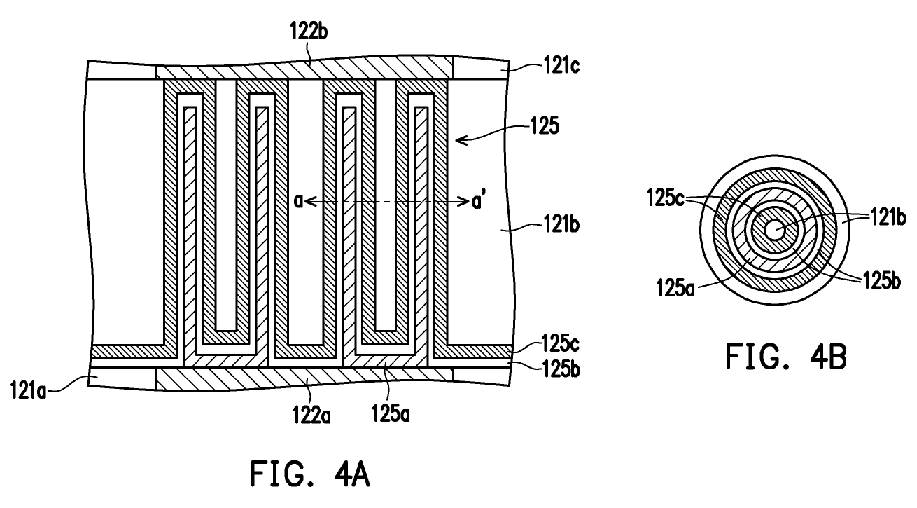

FIG. 4A is a cross-sectional schematic diagram of a passive device 125 according to an embodiment of the present invention. FIG. 4B is a cross-sectional schematic diagram along the line a-a’ of FIG. 4A. The passive device 125 shown in FIG. 4A and FIG. 4B may be disposed in the interposer 100 of FIG. 2 or FIG. 3. Referring to FIG. 4A and FIG. 4B, the passive device 125 is a cylinder capacitor and includes a bottom electrode 125a, a dielectric layer 125b, and a top electrode 125c. The dielectric layer 125b is located between the bottom electrode 125a and the top electrode 125c.

The dielectric structure 121b surrounds the passive device 125 and may be a single-layer or multi-layer structure. The conductive layer 122a is located in the dielectric layer 121a and is electrically connected to the bottom electrode 125a. The conductive layer 122b is located in the dielectric layer 121c and is electrically connected to the top electrode 125c.

In summary, in the semiconductor device of the present invention, the system on chip is bonded to the memory stack layer, and the memory stack layer is located between the system on chip and the interposer. Therefore, the heat dissipation efficiency of the system on chip may be improved.

What is claimed is:

1. A semiconductor device, comprising:
a substrate;
an interposer, bonded to the substrate;
a memory stack layer, bonded to the interposer and electrically connected to the substrate through the interposer, wherein the memory stack layer comprises a plurality of memory dies stacked together; and
a system on chip, bonded to the memory stack layer, wherein the memory stack layer is located between the system on chip and the interposer.

2. The semiconductor device of claim 1, wherein a sidewall of the memory stack layer is aligned with a sidewall of the interposer, and an area of a bottom surface of the memory stack layer is substantially equal to an area of a top surface of the interposer.

3. The semiconductor device of claim 1, wherein the interposer comprises:
a semiconductor substrate, wherein a width of the semiconductor substrate is substantially equal to a width of at least one of the plurality of memory dies; and
a first interconnect structure, located on a first side of the semiconductor substrate.

4. The semiconductor device of claim 1, wherein the interposer comprises:
a semiconductor substrate; and
a first interconnect structure, located on a first side of the semiconductor substrate, wherein the first interconnect structure comprises a passive device.

5. The semiconductor device of claim 1, wherein the interposer comprises an array of redundant memory.

6. The semiconductor device of claim 5, wherein the redundant memory is electrically connected to the memory stack layer.

7. The semiconductor device of claim 1, wherein the interposer comprises a passive device.

8. The semiconductor device of claim 1, further comprising:
a thermal interface material layer, located on a top surface of the system on chip; and
a heat dissipation structure, located on the thermal interface material layer.

9. The semiconductor device of claim 1, further comprising:
an encapsulation layer, laterally surrounding the system on chip, wherein a sidewall of the memory stack layer is aligned with a sidewall of the encapsulation layer.

10. The semiconductor device of claim 9, further comprising:
a thermal interface material layer, extending from a top surface of the system on chip to a top surface of the encapsulation layer; and
a heat dissipation structure, located on the thermal interface material layer.

11. The semiconductor device of claim 1, further comprising:
connection terminals, wherein the system on chip is bonded to an interconnect structure of the memory stack layer through the connection terminals.

12. The semiconductor device of claim 1, further comprising:
an underfill material, located between the system on chip and the memory stack layer.

13. The semiconductor device of claim 1, further comprising:
solder balls, wherein the interposer is electrically connected to the substrate through the solder balls.

14. A manufacturing method of a semiconductor device, comprising:
providing a semiconductor substrate;
forming a first interconnect structure and a first bonding layer on the semiconductor substrate;
forming a memory stack layer on the first interconnect structure, wherein the memory stack layer is bonded to the first bonding layer, wherein the memory stack layer comprises a plurality of memory dies stacked together;
bonding a system on chip to the memory stack layer, wherein the memory stack layer is located between the system on chip and the semiconductor substrate;
forming a second interconnect structure and a plurality of connection terminals on a side of the semiconductor substrate opposite to the first interconnect structure; and
electrically connecting the second interconnect structure to a substrate through the plurality of connection terminals.

15. The manufacturing method of claim 14, wherein an interposer comprises the semiconductor substrate, the first interconnect structure, the first bonding layer, the second interconnect structure and the plurality of connection terminals, wherein a cutting process is performed to align a sidewall of the memory stack layer with a sidewall of the interposer.

16. The manufacturing method of claim 15, wherein before performing the cutting process, the manufacturing method further comprises forming an encapsulation layer laterally surrounding the system on chip, wherein after performing the cutting process, the sidewall of the memory stack layer is aligned with a sidewall of the encapsulation layer.

17. The manufacturing method of claim 14, wherein the system on chip is bonded to the memory stack layer through a hybrid bonding process.
